(19) United States
(12) Patent Application Publication
(10) Pub. No.: US 2004/0164773 A1
(43) Pub. Date: Aug. 26, 2004

(54) Fan driving circuit using an adaptive PWM input signal

(75) Inventor: Taung-Te Ho, Putz City (TW)

Correspondence Address: TROXELL LAW OFFICE PLLC, SUITE 1404, 5205 LEESBURG PIKE, FALLS CHURCH, VA, 22041, US

(73) Assignee: Datech Technology Co., Ltd.

(21) Appl. No.: 10/752,032

(22) Filed: Jan. 7, 2004

(30) Foreign Application Priority Data
Feb. 25, 2003 (TW) 092103961

(51) Int. Cl. H03B 1/00; H02P 5/06

(52) U.S. Cl. 327/108; 388/804

(57) ABSTRACT

This present invention provides a method of fan driving circuit using an adaptive pulse width modulator (PWM) input signal for a signal generator electronically connecting to a fan motor and providing power of the fan motor, the signal generator providing a control signal for controlling ON/OFF of power mentioned. Wherein, the signal generator is a PWM circuit, and this signal generator provides different PWM signal in pursuance of different fan motor loading, enables fan motor stated comprises of adaptive PWM.

### FIELD OF THE INVENTION

The present invention is to provide a method of fan driving circuit using an adaptive pulse width modulator (PWM) input signal, more specifically the invention is related to effect of matching achieving between fan motor and power, furthermore, advantages of this approach such as reducing wastage of fan motor and improving of whole efficiency under controlling of fan motor are available.

### BACKGROUND OF THE INVENTION

A control circuit for heat-dissipation system in Taiwan Patent No.507973 discloses a conventional fan control circuit using a PWM signal. The control circuit includes a signal generator electronically connecting to the heat-dissipation system, providing power of the heat-dissipation system and generating a control signal to control the ON/OFF of the power; and, a power regular apparatus, electronically connecting between the heat-dissipation system and power, paralleling to the signal generator, provides constantly basic power for the circuit of the heat-dissipation system to prevent signals outputting from external devices electronically connecting to the heat-dissipation system from being interfered by the control signal.

Although the fan driving circuit using a PWM signal mentioned above can prevent signals outputting from external devices electronically connecting to the heat-dissipation system from being interfered by the control signal, it is insufficient for the control circuit in real practice. Because of fan motor must change phase first when operating, comprising low velocity, medium velocity and whole velocity, therefore, the output wave diagrams of phase change when fan motor uses the above control circuit or other conventional control circuits are shown in FIG. 7 and FIG. 8. As shown in the above diagrams, the waves when the fan motor changes phase is successive.

Therefore, conventional fan driving circuit using a PWM signal tends to power-consuming increasing by fan motor changing phase in low velocity, medium velocity and whole velocity. Since the required power for the fan increases, it is impossible to save power and operate the fan efficiently. That is, when changes phase, the fan motor is unable to change phase successfully, resulting in low efficiency.

### SUMMARY OF THE INVENTION

The main objective of the present invention is that when phase changes, by means of a control signal at a buffer period, power-consuming would be reduced. The fan motor can change phase successfully and operate efficiently for power-saving, capacity-improving and cost-reducing.

To achieve the above objective, the present invention provides a fan driving circuit using a pulse width modulation (PWM) signal. Wherein, a signal generator electronically connects to a fan motor and provides power for the fan motor. The signal generator generates a control signal for controlling ON/OFF of the power. Wherein, the signal generator generates a control signal at a buffer period when the fan motor changes phase for controlling phase change. Therefore, when phase changes, by means of a control signal at a buffer period, power-consuming would be reduced. The fan motor can change phase successfully and operate efficiently for power-saving, capacity-improving and cost-reducing.

### BRIEF DESCRIPTION OF THE DRAWINGS

The present invention will be better understood from the following detailed description of preferred embodiments of the invention, taken in conjunction with the accompanying drawings, in which

FIG. 1 is a view showing a control circuit diagram of the signal generator according to the first embodiment of the present invention;

FIG. 2 is a view showing an output wave diagram of the signal generator according to the present invention;

FIG. 3 is a view showing a control circuit diagram according to the second embodiment of the present invention;

FIG. 4 is a view showing a wave diagram of voltage, armature current and speed according to the second embodiment of the present invention;

FIG. 5 is a view showing a control circuit diagram according to the third embodiment according to the present invention;

FIG. 6 is a view showing a diagram of basic DC converter and corresponding DC motor terminal voltage according to the present invention;

FIG. 7 is a view showing output wave diagrams of a conventional signal generator; and

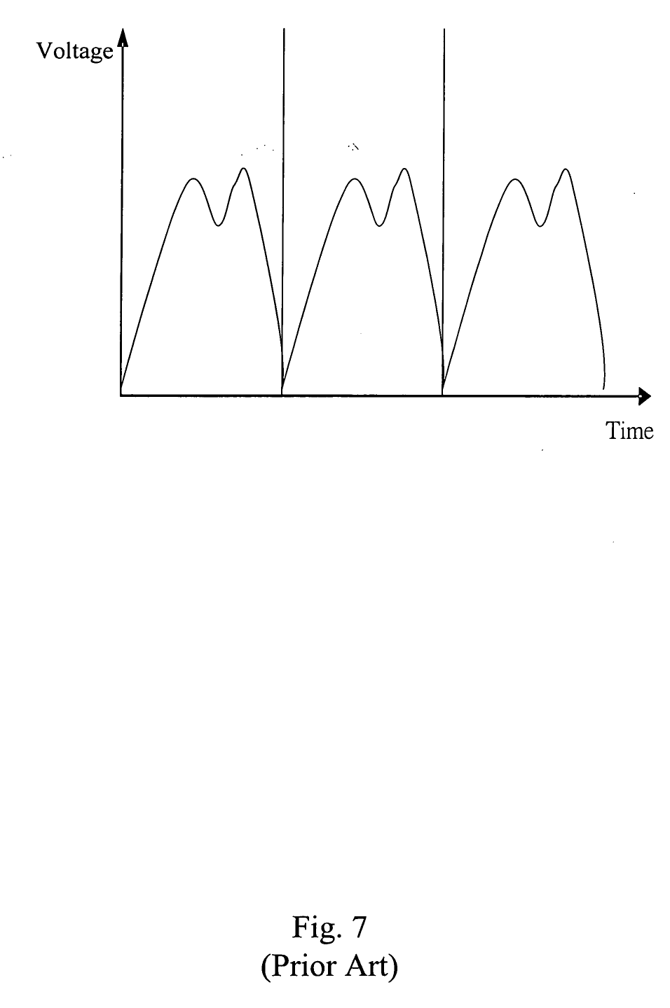

FIG. 8 is a view showing output wave diagrams of a conventional signal generator.

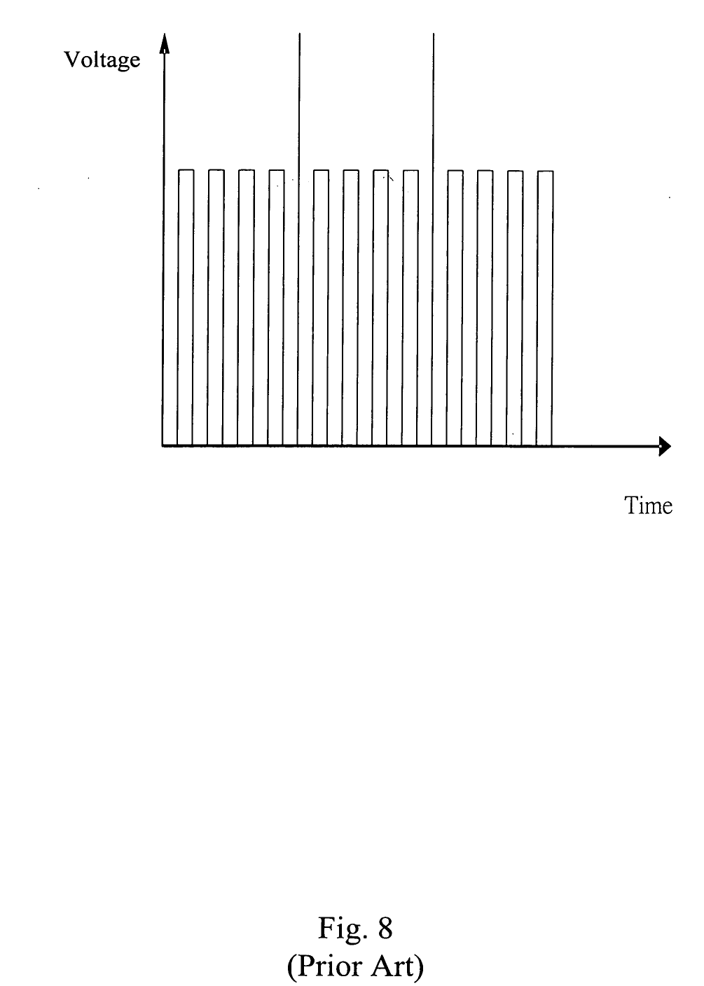

### DESCRIPTION OF THE PREFERRED EMBODIMENTS

The following descriptions of the preferred embodiments are provided to understand the structures and the features of the present invention.

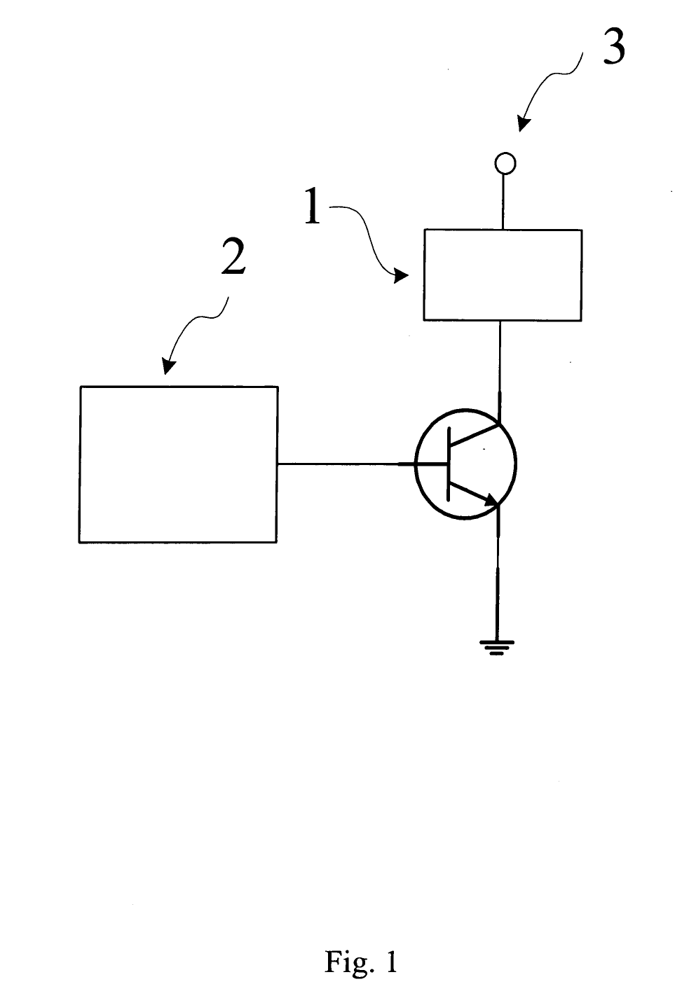

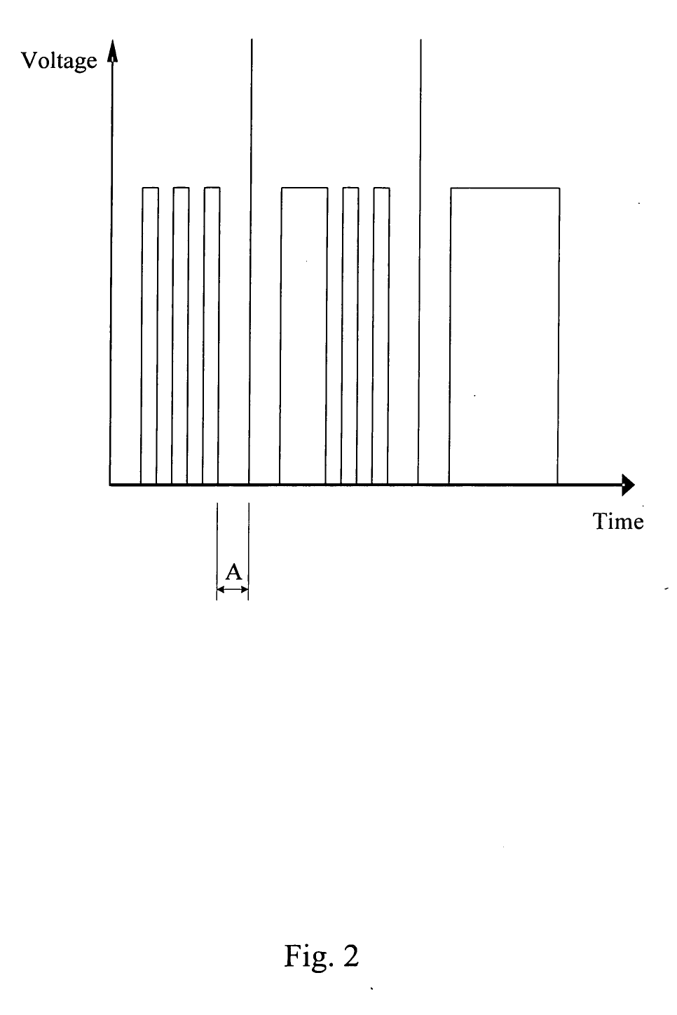

FIG. 1 is a view showing a control circuit diagram of a signal generator according to the first embodiment of the present invention. FIG. 2 is a view showing an output wave diagram of the signal generator according to the present invention. As shown in the diagrams, the present invention provides a fan driving circuit using a PWM signal. Wherein, the signal generator 2 provides control signal to different buffer period. According to this approach, effect of matching achieving between fan motor 1 and power. Furthermore, advantages of this approach such as reducing wastage of fan motor 1 and improving of whole efficiency under controlling of fan motor 1 are available.

The signal generator 2 mentioned above electronically connects to a fan motor 1 and provides power 3 for the fan motor 1. Wherein, the signal generator 2 generates a control signal for controlling ON/OFF of the power 3. Moreover, the signal generator 2 is a fan driving circuit using a PWM signal. The signal generator 2 provides different PWM signal in pursuance of different fan motor loading to enable fan motor 1 stated comprising of adaptive PWM.

The fan motor 1 loading comprises of low velocity, medium velocity and whole velocity. And, the signal generator 2 provides different PWM signal to different loading which comprising low velocity, medium velocity and whole velocity.

The control signal at the buffer period A of the signal generator 2 has a ratio of wave width within a range of 3% to 30%. According to the invention described above, a novel fan driving circuit using a PWN signal, when the fan motor 1 changes phase, by means of the control signal at the buffer period A, power-consuming would be reduced. The fan motor 1 can change phase successfully and operate efficiently for power-saving, capacity-improving and cost-reducing. Wave diagram thereof is shown as FIG. 2, buffer period between said different PWM signals with a ratio of wave width in a range of 3% to 30%.

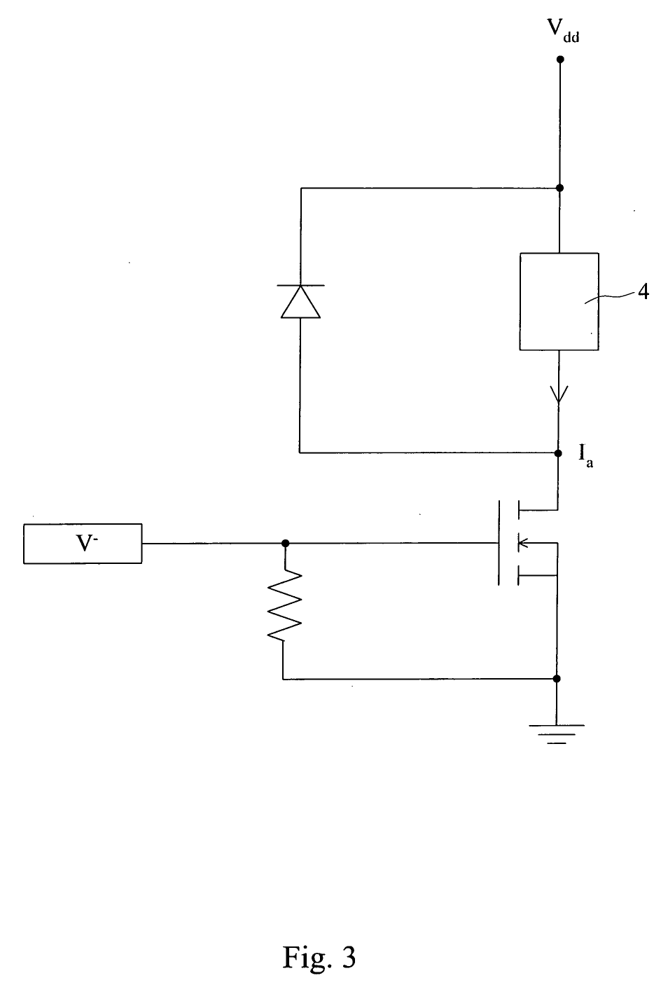

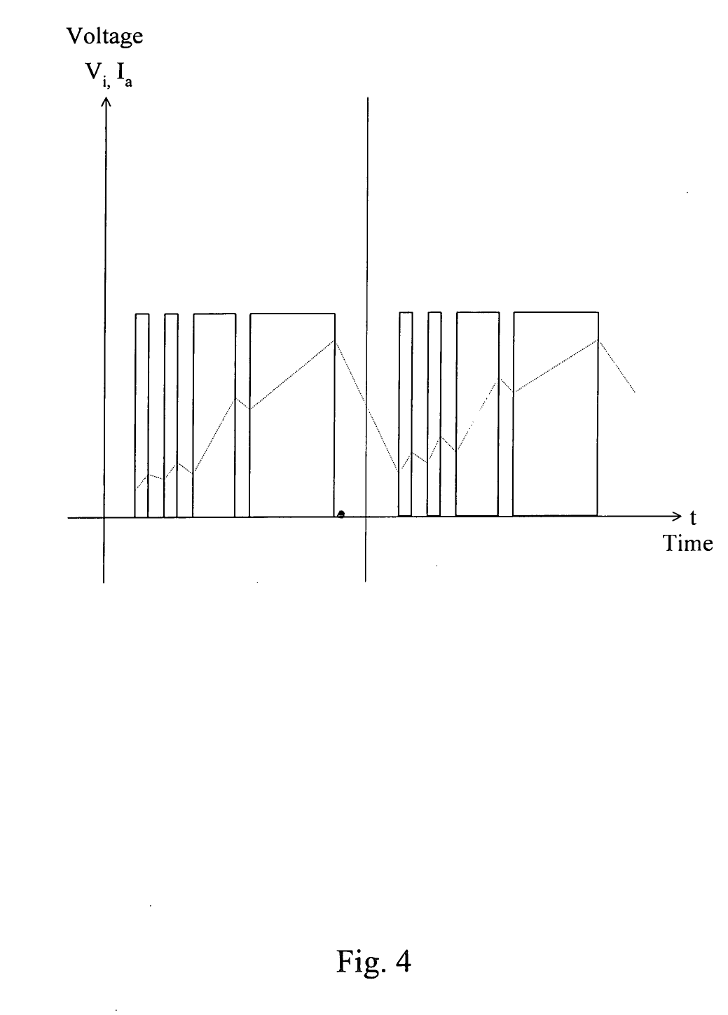

Therefore, a renewed method of a fan driving circuit using an adaptive PWM input signal, which comprises of effect of matching achieving between fan motor and power. Furthermore, advantages of this approach such as reducing wastage of fan motor and improving of whole efficiency under controlling of fan motor are available. FIG. 3 and FIG. 4 respectively show a control circuit diagram according to the second embodiment of the present invention and a wave diagram of voltage, armature current and speed according to the second embodiment of the present invention. As shown in the diagrams, under larger load, transistors will have serious power loss problems. Parts of power will be transferred into heat and be depleted. Since the motor 4 is an inductance load, the current passing through the armature will not drop down to zero immediately when the control voltage Vᵢ of the transistor becomes zero, resulting from the physical characteristic in which current always changes continually. For example, it will reduce constantly along with a specific time constant. Similarly, when Vᵢ suddenly increases, Iₐ will rise constantly along with a specific time constant, therefore, by inertia of the motor, the motor 4 will not promptly stop or transiently operate. As shown in FIG. 4, the current of the motor 4 can be controlled by directly adjusting the pulse width of the input control voltage to further dominate operation of the motor 4. In addition, the FIG. 4 also shows relation between the duty cycle and speed of the input control pulse. The longer the input voltage pulse is, the faster the operating speed of the motor 4 would be, and vice versa.

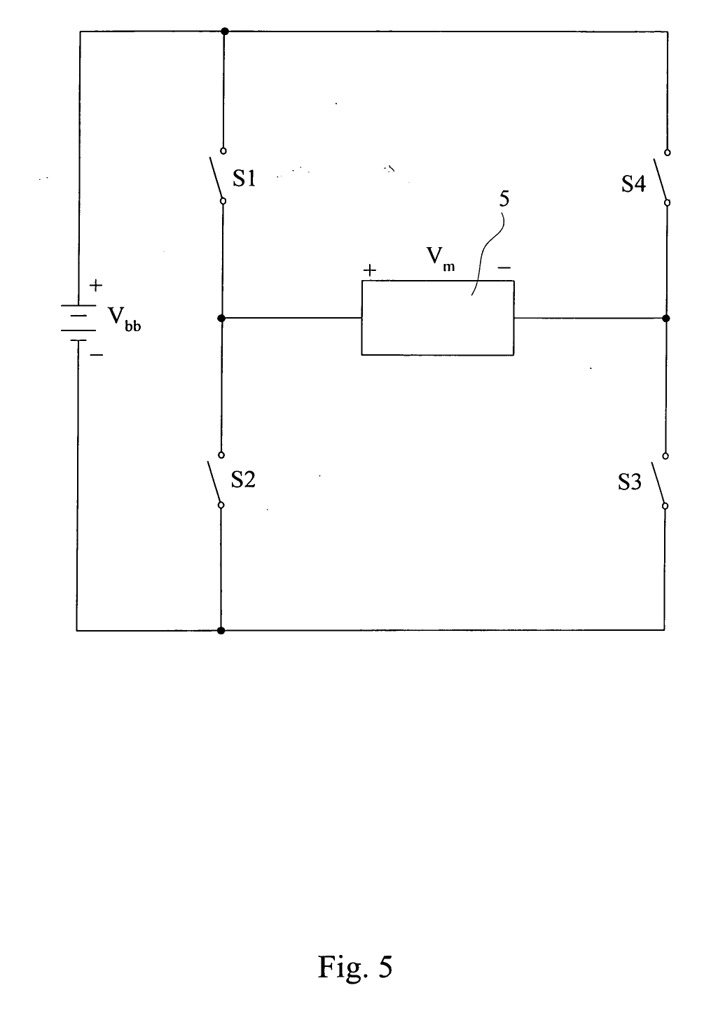

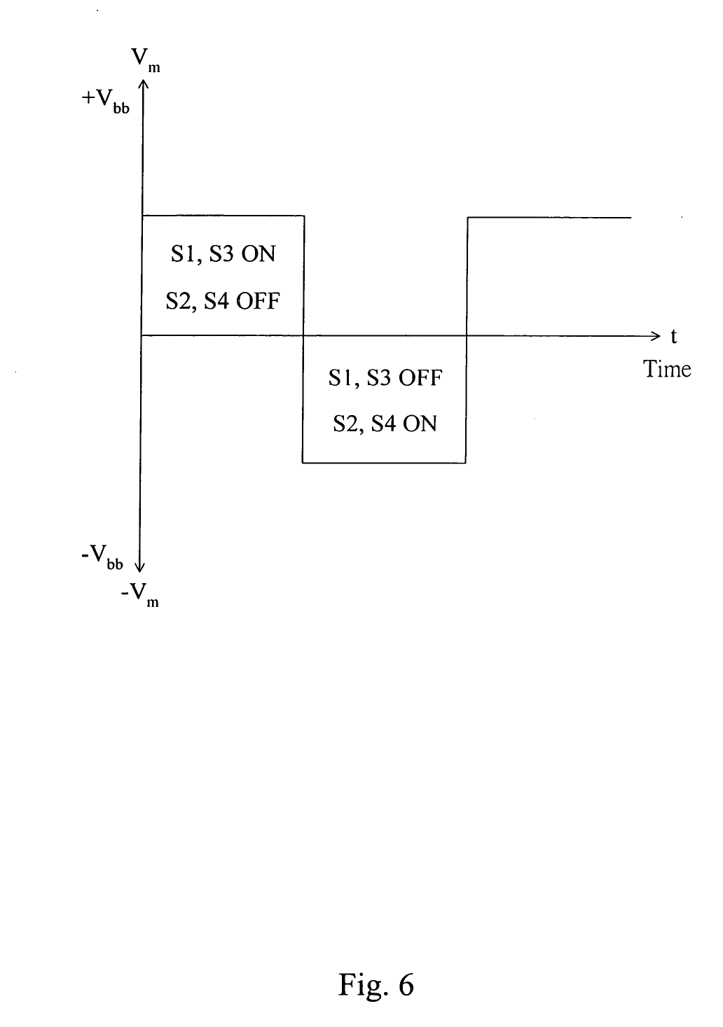

FIG. 5 and FIG. 6 respectively show a control circuit diagram according to a third embodiment of the present invention and a diagram of basic DC converter and corresponding DC motor terminal voltage of the present invention. As shown in the diagrams, to solve the shortcomings of using a relay to control trend, in the third embodiment of the present invention, the basic logic structure is: gathering S1 with S3 into a group, S2 with S4 into another group when switching. The two groups will operate together and become mutual exclusive for preventing occurrence of short circuits. Two rules are described as follows.

The terminal voltage Vₘ of the motor 5 is equal to +V_{bb} when S1, S3 are ON and S2, S4 are OFF. Meanwhile, the motor 5 operates clock-wise.

The terminal voltage Vₘ of the motor 5 is equal to −V_{bb} when S1, S3 are OFF and S2, S4 are ON. Meanwhile, the motor 5 operates underclock-wise.

The above control rules cooperating with the fan driving circuit using a PWM signal of the present invention can efficiently control the motor.

In summation of the foregoing section, the invention herein fully complies will all new patent application requirement and is hereby submitted to the patent bureau for review and the granting of the commensurate patent rights.

The present invention may be embodied in other specific forms without departing from the spirit of the essential attributes thereof; therefore, the illustrated embodiment should be considered in all respects as illustrative and not restrictive, reference being made to the appended claims rather than to the foregoing description to indicate the scope of the invention.

What is claimed is:

1. A fan driving circuit using an adaptive PWM input signal for a signal generator electronically connecting to a fan motor and providing power of said fan motor, said signal generator generating a control signal for controlling ON/OFF of said power; which is characterized in that,
said signal generator being a pulse width modulator (PWM) circuit, different PWM signal in pursuance of different fan motor loading which comprises low velocity, medium velocity and whole velocity, a buffer period between said different PWM signal with a ratio of wave width in a range of 3% to 30%.
